(19) United States
(12) Patent Application Publication
(10) Pub. No.: US 2008/0237761 A1
(43) Pub. Date: Oct. 2, 2008

(54) SYSTEM AND METHOD FOR ENHANCING LIGHT SENSITIVITY FOR BACKSIDE ILLUMINATION IMAGE SENSOR

(75) Inventors: Shih-Chi Fu, Taipei City (TW); Chia-Shiung Tsai, Hsin-Chu (TW); Gwo-Yuh Shiau, Hsinchu-City (TW); Ming Chyi Liu, Hsinchu City (TW); Feng-Jia Shiu, Hsinchu County (TW); Tzu-Hsuan Hsu, Kaohsiung City (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/695,363

(22) Filed: Apr. 2, 2007

(51) Int. Cl. H01L 31/0232

(52) U.S. Cl. 257/432; 257/E31.127

(57) ABSTRACT

A system and method for enhancing light sensitivity of a back-side illumination image sensor are described. An integrated circuit includes a substrate and an image sensor device comprising at least one transistor formed over a first surface of the substrate and a photosensitive region. A color filter is disposed over a second surface of the substrate opposite the first surface thereof. A micro-lens structure is disposed between the second surface of the substrate and the color filter.

### BACKGROUND

Solid state image sensors, such as CMOS image sensors (“CIS”) and charge-coupled devices (“CCD”), are used in various imaging devices, such as video cameras. Backside illuminated (“BSI”) image sensors have been introduced as an alternative to front side illuminated (“FSI”) image sensors to address fill factor problems associated with FSI sensors. As the name implies, BSI image sensors receive light through a backside surface of a substrate supporting the image sensor circuitry; as a result, the substrate must be extremely thin. In general, BSI technology promises a higher sensitivity, lower cross-talk, and comparable quantum efficiency as compared to FSI, since the substrate is thinner, thereby rendering the photo-sensitive region closer to the color filter. However, currently, for a variety of reasons, the sensitivity of BSI image sensors is still not favorably comparable to FSI image sensors.

### BRIEF DESCRIPTION OF THE DRAWINGS

The features and advantages of a system and method for enhancing light sensitivity for backside illumination image sensor in accordance with an embodiment will be more clearly understood from the following description taken in conjunction with the accompanying drawings in which like reference numerals designate similar or corresponding elements, regions, and portions, and in which:

FIG. 1 illustrates a BSI image sensor in accordance with one embodiment.

FIG. 2 illustrates a BSI image sensor in accordance with another embodiment.

FIG. 3 illustrates a BSI image sensor in accordance with another embodiment.

FIG. 4 illustrates a BSI image sensor in accordance with yet another embodiment.

### DETAILED DESCRIPTION

It is to be understood that the following disclosure provides many different embodiments, or examples, that may benefit from the present invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

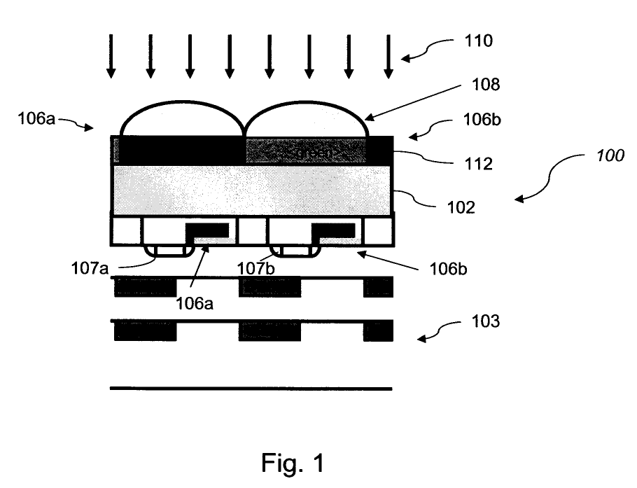

FIGS. 1-4 provide various different embodiments of a BSI image sensor. It is understood that different features and elements from one embodiment can be applied to another embodiment of the present disclosure to form additional embodiments.

FIG. 1 illustrates an integrated circuit 100 for implementing a BSI image sensor in accordance with one embodiment. As shown in FIG. 1, the integrated circuit 100 comprises a substrate 102. The substrate 102 includes silicon in a crystalline structure. The substrate 102 may alternatively or additionally include other elementary semiconductor such as germanium, or diamond. The substrate 102 may also include a compound semiconductor such as silicon carbide, gallium arsenic, indium arsenide, or indium phosphide. The substrate 102 having thickness less than about 15 micrometer. The substrate 102 may include various p-type doped regions and/or n-type doped regions configured and coupled to form various devices and functional features. All doping features may be achieved using a process such as ion implantation or diffusion in various steps and techniques. The substrate 102 may include other features such as a shallow trench isolation (STI), an epi layer, a semiconductor on insulator (SOI) structure, or combinations thereof.

In the present embodiment, a multilayer interconnect (MLI) and an inter-level dielectric (ILD), collectively designated with the reference numeral 103, are provided on the semiconductor substrate 102. FIG. 1 illustrates an exemplary MLI structure with two metal layers. The MLI further includes contact/via features configured between the layers and/or the semiconductor substrate and coupling the both. The MLI may alternatively or collectively include other conductive materials such as copper alloy, titanium, titanium nitride, tantalum, tantalum nitride, tungsten, polysilicon, metal silicide, or combinations. The metal silicide may include nickel silicide, cobalt silicide, tungsten silicide, tantalum silicide, titanium silicide, platinum silicide, erbium silicide, palladium silicide, or combinations thereof.

FIG. 1 also illustrates an exemplary passivation structure, including the ILD. The ILD is disposed on the semiconductor substrate 102 to electrically isolate features such as the MLI. The ILD may include a pre-metal dielectric layer (PMD) and various inter-metal dielectric layers (IMD) and various etch stop/barrier layers (or referred to as a barrier layer for simplicity) interposed between adjacent IMD. Each of PMD and IMD layers may have a thickness ranging between about 0.1 micron and 1 micron. IMD and PMD may include silicon dioxide such as undoped silica glass (USG), silicon nitride, silicon oxynitride, polyimide, spin-on glass (SOG), fluoride-doped silicate glass (FSG), carbon doped silicon oxide such as SiCOH, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), and/or other suitable materials.

One or more imaging sensor elements 104 are disposed in the semiconductor substrate 110. For the sake of example, two image sensor elements, designated individually as elements 104a and 104b, are illustrated in the figure. The sensor elements 104 include a light-sensing region 106 which may be a doped region having N-type and/or P-type dopants formed in the semiconductor substrate 102 by a method such as diffusion or ion implantation. In furtherance of the present example, two light-sensing regions, designated individually as regions 106a and 106b, are illustrated in the figure. The light-sensing regions 106 may have a doping concentration ranging between about 10¹⁴ and 10²¹ atoms/cm³. The light-sensing regions may have a surface area ranging between about 10% and 80% of the area of the associated sensor element, being operable to receive light (or other form of radiation energy from an object to be imaged). Examples of the sensor element 104 include a photodiode, a complimentary metal-oxide-semiconductor (CMOS) image sensor, a charged coupling device (CCD) sensor, an active sensor, a passive sensor, and/or other types of devices diffused or otherwise formed in the substrate 102. As such, the sensor element 104 may include conventional and/or future-developed image sensing devices. For the sake of further example, two image sensor elements 104a, 104b, and two light-sensing regions 106a, 106b are illustrated in the figure.

The sensor elements 104 are provided here only for example. The semiconductor device 100 may include a plurality of sensor elements disposed in an array or other proper configuration. The plurality of sensor elements may be designed to have various sensor types. For example, one group of sensor elements may be CMOS image sensors and another group of sensor elements may be passive sensors. Moreover, the sensor elements 104 may include color image sensors and/or monochromatic image sensors. At least one transistor 107, represented in FIG. 1 by transistors 107a, 107b, is disposed on a first surface of the substrate 102 over at least one photosensitive region 106. The photosensitive region 106 has a doping depth greater than or equal to 1.0 micrometers.

At least one transistor 107, represented in FIG. 1 by transistors 107a, 107b, is disposed on a first surface of the substrate 102 over at least one photosensitive region 106. A micro-lens structure 108 is disposed above a second surface of the substrate 102 opposite the first surface thereof such that the image sensor is illuminated by light 110 passing through a color filter 112, the micro-lens structure 108, and the substrate 102. For the sake of further example, red and green wavelength filters are illustrated, it being understood that various filters can be used, as desired, for different wavelengths (colors) and so forth.

Due to the high n-value of the substrate, the back focus length (“BFL”) is extended in the BSI image sensor, such as embodied in integrated circuit 100. However, the high k-value of the substrate (e.g., approximately 0.2 for silicon), results in the blue ray sensitivity deteriorating with the long focus length. Moreover, the single micro-lens structure 108, which is formed by reflow process, does not supply enough light-bending power due primarily to the aspect-ratio constraints of the material.

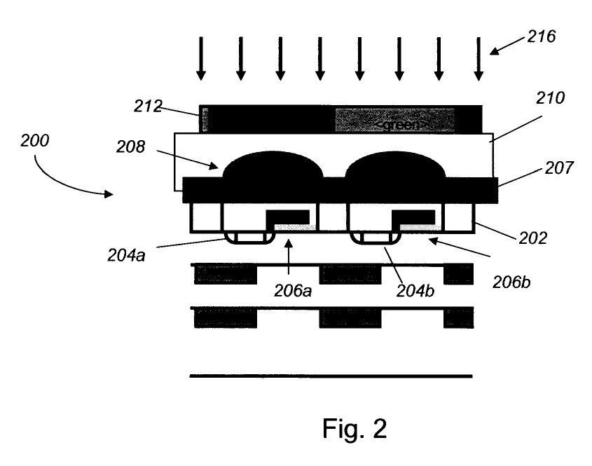

FIG. 2 illustrates an integrated circuit 200 for implementing a BSI image sensor, in this case, a CIS, in accordance with another embodiment of the present invention. As shown in FIG. 2, the integrated circuit 200 comprises a substrate 202, which may comprise, for example, silicon (Si), silicon germanium (SiGe), or germanium (Ge). The substrate 402 having thickness less than about 15 micrometer, preferably between about 1.5 micrometer and about 10 micrometer. At least one transistor, represented in FIG. 2 by transistors 204a, 204b, is disposed on a first surface of the substrate 202 over at least one photosensitive region, represented in FIG. 2 by regions 206a, 206b. The photosensitive region 206a or 206b have a doping depth greater than or equal to 1.0 micrometers. An insulating layer 207, an inner micro-lens structure 208, a planarizing layer 210, and a color filter 212 are disposed in that order above a second surface of the substrate 202 opposite the first surface thereof. The image sensor is illuminated by light 216 passing through the color filter 212, planarizing layer 210, inner micro-lens structure 208, insulating layer 207, and substrate 202. It will be recognized that the provision of the inner micro-lens structure 208 between the second surface and the color filter 212 supplies additional light-bending power for the incident light 216, thereby enhancing the sensitivity of the circuit 200 to BSI. The inner micro-lens structure 208 can provide a flexible lens-shape design for increased versatility.

In one embodiment, the micro-lens structure 208 comprises a nitrogen-containing material, such as silicon nitride, and has an n-value of less than approximately 2 and preferably between 1.6 and 2.0. The insulating layer 207 may comprise a dielectric material, such as oxide or oxynitride, and may be formed using a chemical vapor deposition (“CVD”) or spin-on method. The planarizing layer 210 may comprise an organic material and may be formed using a spin-coating method.

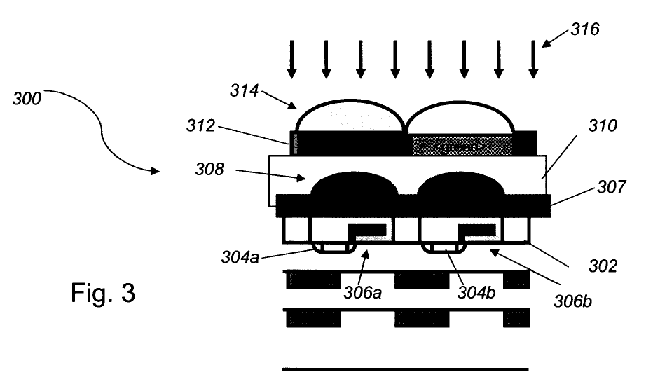

FIG. 3 illustrates an integrated circuit 300 for implementing a BSI image sensor, in this case, a CIS, in accordance with yet another embodiment. As shown in FIG. 3, the integrated circuit 300 comprises a substrate 302, which may comprise, for example, silicon (Si), silicon germanium (SiGe), or germanium (Ge). At least one transistor, represented in FIG. 3 by transistors 304a, 304b, is disposed on a first surface of the substrate 302 over at least one photosensitive region, represented in FIG. 3 by regions 306a, 306b. Similar to the structure of the integrated circuit 200, the integrated circuit 300 includes an insulating layer 307, an inner micro-lens structure 308, a planarizing layer 310, and a color filter 312 disposed in that order over a second surface of the substrate 302 opposite the first surface thereof. In addition, the integrated circuit 300 includes an outer micro-lens structure 314 disposed above the color filter 312. The image sensor is illuminated by light 316 passing through the outer micro-lens structure 314, color filter 312, planarizing layer 310, inner micro-lens structure 308, insulating layer 307, and substrate 302.

In one embodiment, the inner micro-lens structure 308 comprises a nitrogen-containing material, such as silicon nitride, and has an n-value of less than approximately 2 and preferably between 1.6 and 2.0. In one embodiment, the outer micro-lens structure 314 comprises an organic material and has an n-value of 1.6˜1.8. In one embodiment, the radius of curvature of the inner micro-lens structure 308 is greater than or equal to that of the outer micro-lens structure 314. In one embodiment, the n-value of the inner micro-lens structure 308 is greater than or equal to that of the outer micro-lens structure 314. The insulating layer 307 may comprise a dielectric material, such as oxide or oxynitride, and may be formed using a chemical vapor deposition (“CVD”) or spin-on method. The planarizing layer 310 may comprise an organic material and may be formed using a spin-coating method.

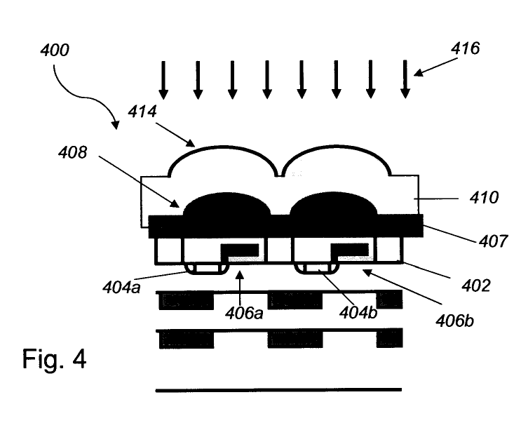

FIG. 4 illustrates an integrated circuit 400 for implementing a BSI image sensor, in this case, a CIS, in accordance with yet another embodiment. As shown in FIG. 4, the integrated circuit 400 is similar to the integrated circuit 300 of FIG. 3, except that it does not have a color filter. Specifically, the integrated circuit 400 comprises a substrate 402, which may comprise, for example, silicon (Si), silicon germanium (SiGe), or germanium (Ge). At least one transistor, represented in FIG. 4 by transistors 404a, 404b, is disposed on a first surface of the substrate 402 over at least one photosensitive region, represented in FIG. 4 by regions 406a, 406b. The photosensitive region 406a or 406b have a doping depth greater than or equal to 1.0 micrometers. Similar to the structure of the integrated circuit 300, the integrated circuit 400 includes an insulating layer 407, an inner micro-lens structure 408, a planarizing layer 410, and an outer micro-lens structure 414 disposed in that order above a second surface of the substrate 402 opposite the first surface thereof. The image sensor is illuminated by light 416 passing through the outer micro-lens structure 414, planarizing layer 410, inner micro-lens structure 408, insulating layer 407, and substrate 402.

In one embodiment, the inner micro-lens structure 408 comprises a nitrogen-containing material, such as silicon nitride, and has an n-value of less than approximately 2 and preferably between 1.6 and 2.0. In one embodiment, the outer micro-lens structure 414 comprises an organic material and has an n-value of 1.6˜1.8. In one embodiment, the radius of curvature of the inner micro-lens structure 408 is greater than or equal to that of the outer micro-lens structure 414. In one embodiment, the n-value of the inner micro-lens structure 408 is greater than or equal to that of the outer micro-lens structure 414. The insulating layer 407 may comprise a dielectric material, such as oxide or oxynitride, and may be formed using a chemical vapor deposition (“CVD”) or spin-on method. The planarizing layer 410 may comprise an organic material and may be formed using a spin-coating method.

One embodiment is an integrated circuit that includes a substrate and an image sensor device that includes at least one transistor formed over a first surface of the substrate and a photosensitive region. A color filter is disposed over a second surface of the substrate opposite the first surface thereof. A micro-lens structure is disposed between the second surface of the substrate and the color filter.

Another embodiment is an integrated circuit that includes a substrate and an image sensor device that includes at least one transistor formed over a first surface of the substrate and a photosensitive region. A first micro-lens structure is formed over a second surface of the substrate opposite the first surface thereof. A color filter is disposed over first micro-lens structure and a second micro-lens structure is formed over the color filter.

Another embodiment is an integrated circuit that includes a substrate and an image sensor device that includes at least one transistor formed over a first surface of the substrate and a photosensitive region. A first micro-lens structure comprising a first material is formed over a second surface of the substrate opposite the first surface thereof. A second micro-lens structure comprising a second material is formed over the first micro-lens structure. The first material is different from the second material.

Another embodiment is an integrated circuit including a substrate and an image sensor device that includes at least one transistor formed over a first surface of the substrate and a photosensitive region. A first micro-lens structure is formed over a second surface of the substrate opposite the first surface thereof and a second micro-lens structure is formed over the first micro-lens structure. A radius of curvature of the first micro-lens structure is greater than or equal to a radius of curvature of the second micro-lens structure.

While the preceding description shows and describes one or more embodiments, it will be understood by those skilled in the art that various changes in form and detail may be made therein without departing from the spirit and scope of the present disclosure. Therefore, the claims should be interpreted in a broad manner, consistent with the present disclosure.

What is claimed is:

1. An integrated circuit comprising:
a substrate;
an image sensor device comprising at least one transistor formed over a first surface of the substrate and a photosensitive region;
a color filter disposed over a second surface of the substrate opposite the first surface thereof; and
a micro-lens structure disposed between the second surface of the substrate and the color filter.

2. The integrated circuit of claim 1 wherein the thickness of the substrate is between approximately 1.5 micrometers and approximately 10 micrometers.

3. The integrated circuit of claim 1 further comprising an insulating layer disposed between the second surface of the substrate and the micro-lens structure.

4. The integrated circuit of claim 1 further comprising a planarizing layer disposed between the micro-lens structure and the color filter.

5. The integrated circuit of claim 1 wherein the micro-lens structure has an n-value of less than or equal to approximately 2.0.

6. The integrated circuit of claim 1 wherein the photosensitive region has a doping depth greater than or equal to 1.0 micrometers.

7. An integrated circuit comprising:
a substrate;
an image sensor device comprising at least one transistor formed over a first surface of the substrate and a photosensitive region;
a first micro-lens structure formed over a second surface of the substrate opposite the first surface thereof;
a color filter disposed over first micro-lens structure; and
a second micro-lens structure formed over the color filter.

8. The integrated circuit of claim 7 wherein a thickness of the substrate is less than approximately 15 micrometers.

9. The integrated circuit of claim 7 wherein an n-value of the first micro-lens structure is greater than or equal to an n-value of the second micro-lens structure.

10. The integrated circuit of claim 7 wherein a radius of curvature of the first micro-lens structure is greater than or equal to a radius of curvature of the second micro-lens structure.

11. The integrated circuit of claim 7 wherein the first micro-lens structure comprises a first material and the second micro-lens structure comprises a second material and wherein the first and second materials are different.

12. The integrated circuit of claim 11 wherein the first material comprises a nitrogen-based material.

13. The integrated circuit of claim 11 wherein the second material comprises an organic material.

14. An integrated circuit comprising:
a substrate;
an image sensor device comprising at least one transistor formed over a first surface of the substrate and a photosensitive region;
a first micro-lens structure comprising a first material formed over a second surface of the substrate opposite the first surface thereof; and
a second micro-lens structure comprising a second material formed over the first micro-lens structure;
wherein the first material is different from the second material.

15. The integrated circuit of claim 14 wherein an n-value of the first micro-lens structure is greater than or equal to an n-value of the second micro-lens structure.

16. The integrated circuit of claim 14 wherein a radius of curvature of the first micro-lens structure is greater than or equal to a radius of curvature of the second micro-lens structure.

17. The integrated circuit of claim 14 further comprising a color filter disposed between the first micro-lens structure and the second micro-lens structure.

18. The integrated circuit of claim 14 wherein the first material comprises a nitrogen-based material and the second material comprises an organic material.

19. An integrated circuit comprising:
a substrate;
an image sensor device comprising at least one transistor formed over a first surface of the substrate and a photosensitive region;
a first micro-lens structure formed over a second surface of the substrate opposite the first surface thereof, the first micro-lens having a first n-value, a first curvature radius, and being formed of a first material; and
a second micro-lens structure formed over the first micro-lens structure, the second micro-lens having a second n-value, a second curvature radius, and being formed of a second material;
wherein at least one of either the first curvature radius, the first n-value, or the first material is different from at least one of the corresponding second curvature radius, second n-value, or second material.

20. The integrated circuit of claim 19 wherein the first n-value is greater than the second n-value and the first curvature radius is greater than the second curvature radius.
